(19) United States
(12) Patent Application Publication
(10) Pub. No.: US 2009/0053897 A1
(43) Pub. Date: Feb. 26, 2009

(54) Method of fabricating a circuit board

(75) Inventor: Ryoichi Watanabe, Osaka (JP)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,945

(22) Filed: Apr. 8, 2008

(30) Foreign Application Priority Data
Aug. 21, 2007 (KR) 10-2007-0084071

(51) Int. Cl. H01L 21/311

(52) U.S. Cl. 438/700; 257/E21.249

(57) ABSTRACT

A method of fabricating a circuit board is disclosed. The method includes: forming a trench in a base and forming an electroless plating layer over a surface of the base and an inner surface of the trench; providing a carrier, on one side of which a plating resist is coated; forming a transcribed part on the surface of the base by stacking the carrier onto the base and transcribing the plating resist onto the surface of the base; forming a pattern in the trench by plating, and removing the transcribed part; and removing portions of the electroless plating layer and the pattern. This method makes it possible to form circuit patterns with a uniform thickness and to provide high workability.

### CROSS-REFERENCE TO RELATED APPLICATIONS

This application claims the benefit of Korean Patent Application No. 10-2007-0084071 filed with the Korean Intellectual Property Office on Aug. 21, 2007, the disclosure of which is incorporated herein by reference in its entirety.

### BACKGROUND

1. Technical Field

The present invention relates to a method of fabricating a circuit board.

2. Description of the Related Art

Rapid developments in state-of-the-art electronic products, such as cell phones and digital cameras, etc., are creating products that provide lighter weight, smaller sizes, lower thicknesses, and greater varieties of functions. Accordingly, there is a need for higher speeds and higher densities in LSI (large scale integration) packages, as well as for higher densities in build-up boards. Semi-additive processes are currently used in manufacturing circuit boards that are thus being implemented in higher densities and higher levels of integration, while methods with greater precision than semi-additive processes, such as laser ablation and imprinting, are also being used. In methods using laser ablation or imprinting, circuits may be formed by forming fine-lined trenches using laser or imprinting, and then filling a conductive material into the trenches using plating, etc.

### SUMMARY

An aspect of the invention is to provide a method of fabricating a circuit board, which can provide a circuit pattern of a uniform thickness, and which can provide high workability.

One aspect of the invention provides a method of fabricating a circuit board, which includes: forming a trench in a base and forming an electroless plating layer over a surface of the base and an inner surface of the trench; providing a carrier, on one side of which a plating resist is coated; forming a transcribed part on the surface of the base by stacking the carrier onto the base and transcribing the plating resist onto the surface of the base; forming a pattern in the trench by plating, and removing the transcribed part; and removing portions of the electroless plating layer and the pattern.

Embodiments of the method of fabricating a circuit board according to an aspect of the invention may include one or more of the following features. For example, the trench may be formed by a laser ablation process or an imprinting process. After forming the trench, an operation may further be included for removing residue from forming the trench and roughening the surface of the base by applying a chemical treatment or a plasma treatment on the surface of the base.

In providing the carrier having a plating resist coated on one side, the plating resist can be a resin in one of a liquid, gel, and semi-cured state, stacked on the carrier. The plating resist can be made from one of a polystyrene resin, an acrylic resin, and an epoxy resin, which provide high detachability. A thickness of the transcribed part may be substantially the same as or may be lower than a thickness of the plating resist.

The carrier may be made from polyethylene terephthalate, and the portions of the electroless plating layer and the pattern may be removed by flash etching.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of fabricating a circuit board according to an embodiment of the present invention.

FIG. 2 is a cross-sectional view after forming a trench in the base, in a method of fabricating a circuit board according to an embodiment of the invention.

FIG. 3 is a cross-sectional view after forming an electroless plating layer over the surfaces of the base and the trench by performing electroless plating over the base in FIG. 2.

FIG. 4 is a cross-sectional view after providing a carrier having a plating resist formed on one side, over the base on which the electroless plating layer 140 is formed.

FIG. 5 is a cross-sectional view after stacking the carrier having the plating resist on the surface of the base in FIG. 4.

FIG. 6 is a cross-sectional view after the plating resist is transcribed onto the surface of the base.

FIG. 7 is a cross-sectional view after forming a pattern in the trench by copper plating.

FIG. 8 is a cross-sectional view after removing the transcribed part of the plating resist in FIG. 7.

FIG. 9 is a cross-sectional view after removing portions of the electroless plating layer and the pattern.

FIG. 10 is a cross-sectional view after removing the carrier, illustrating the transcribed part formed on the surface of the base to be thinner than the plating resist.

### DETAILED DESCRIPTION

As the invention allows for various changes and numerous embodiments, certain embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

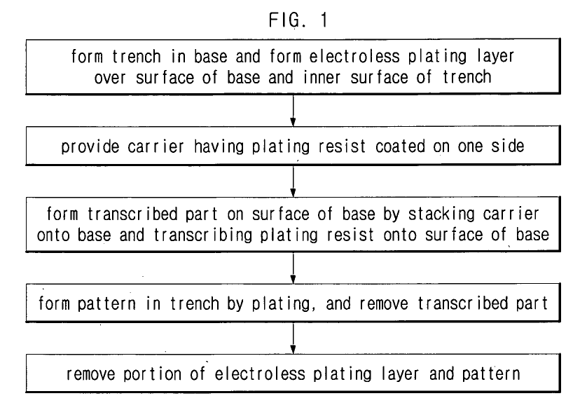

The following describes a method of fabricating a circuit board according to an embodiment of the present invention with reference to FIG. 1 through FIG. 9.

FIG. 1 is a flowchart illustrating a method of fabricating a circuit board according to an embodiment of the invention.

Referring to FIG. 1, a method of fabricating a circuit board according to an embodiment of the invention may include forming a trench in a base and forming an electroless plating layer over a surface of the base and an inner surface of the trench; providing a carrier, on one side of which a plating resist is coated; forming a transcribed part on the surface of the base by stacking the carrier onto the base and transcribing the plating resist onto the surface of the base; forming a pattern in the trench by plating, and removing the transcribed part; and removing portions of the electroless plating layer and the pattern.

In the method of fabricating a circuit board according to this embodiment, a plating resist may be formed on the surface of a carrier, made from a film, etc., and may be transcribed onto a base, in which a trench is formed. In this way, the plating resist can readily be formed on only the surface of the base. Thus, since the plating resist is not placed inside the trench, the thickness of the pattern can be made uniform, and the occurrence of pin holes can be avoided, so that a circuit board of high reliability may be provided.

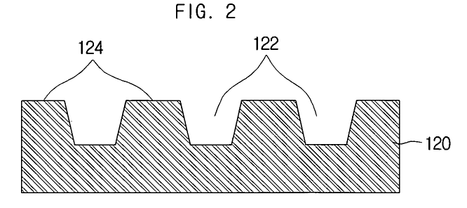

The operations used in method of fabricating a circuit board according to this embodiment will be described in further detail with reference to FIGS. 2 to 10.

FIG. 2 is a cross-sectional view after forming a trench 122 in the base 120, in a method of fabricating a circuit board according to an embodiment of the invention.

The base 120 can be formed from a general thermosetting resin, etc. While FIG. 2 illustrates a base 120 composed of one layer, this is intended merely for convenient description, and it will be appreciated that multiple layers of other bases 120 may be stacked above or below the base 120. Methods of forming a trench 122 in the base 120 may include laser ablation methods and imprinting methods, etc. The trench 122 may be filled in later with a conductive material by plating, and thus may have a constant width and thickness. The thickness of the circuit pattern may be determined by the amount of plating filled in the trench 122.

Although it is not shown in the drawings, in cases where the base 120 is stacked in multiple layers, the base 120 may include not only the trench 122 for forming circuit patterns, but also a trench for forming a via hole that connects circuit patterns positioned on different layers.

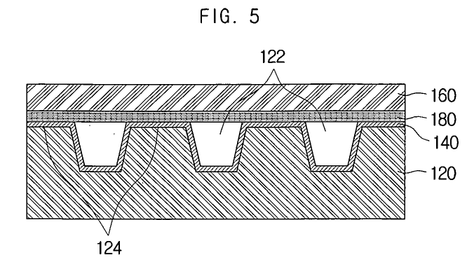

If the trench is formed by a laser ablation method or an imprinting method, residue may be found on the surface 124 of the base. To remove such residue, the surface 124 of the base 120 can be processed using chemicals or using a plasma treatment. Processing the surface 124 of the base 120 in this manner using chemical treatment or plasma treatment can roughen the surface 124 of the base 120, to increase the adhesion to the plating resist 180 (FIG. 5).

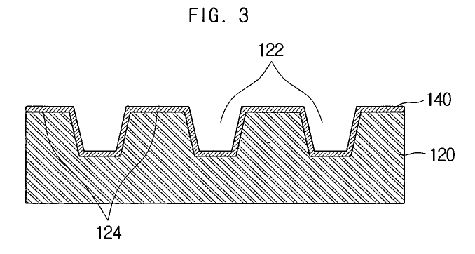

FIG. 3 is a cross-sectional view after forming an electroless plating layer 140 over the surface 124 of the base 120 and in the trench 122 by performing electroless plating over the base 120 in FIG. 2.

Referring to FIG. 3, an electroless plating layer 140 having a thickness of several or several tens of micrometers may be formed on the surface of the base 120 using copper (Cu). The electroless plating layer 140 can be formed not only on the surface 124 of the base 120 but also on the inner surfaces of the trench 122. The electroless plating layer 140 may serve as a seed layer in a later process of filling the inside of the trench 122 by plating.

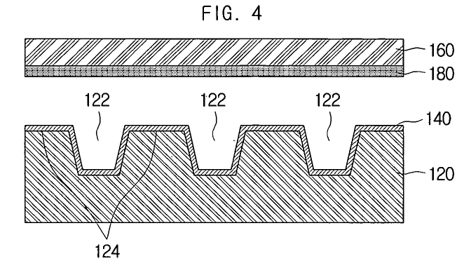

FIG. 4 is a cross-sectional view after providing a carrier 160, which has a plating resist 180 formed on one side, over the base 120 on which the electroless plating layer 140 is formed.

Referring to FIG. 4, a plating resist 180 having a uniform thickness may be coated on one side of the carrier 160. The carrier 160 can be formed from a film, such as of polyethylene terephthalate, etc. The plating resist 180 can be made from one of a polystyrene resin, an acrylic resin, and an epoxy resin, which are high in detachability and which display superb resistance to plating chemicals after drying. The plating resist 180 can be formed by applying or coating a liquid state, gel state, or semi-cured state resin onto one side of the carrier 160. Work efficiency can be increased if the carrier 160, on which the plating resist 180 may be formed, is used wound around a roller.

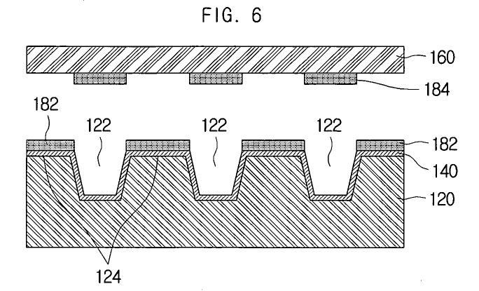

FIG. 5 is a cross-sectional view after stacking the carrier 160, on which the plating resist 180 is formed, on the surface 124 of the base 120 in FIG. 4, and FIG. 6 is a cross-sectional view after the plating resist 180 is transcribed onto the surface 124 of the base 120.

Referring to FIG. 5, the carrier 160 may be positioned on the surface 124 of the base 120, and then particular levels of pressure and heat may be applied so that the plating resist 180 may be transcribed onto the surface 124 of the base 120. Here, if the carrier 160 is wound around a roller, the carrier 160 wound on the roller can be positioned over the base 120 by unwinding the carrier 160, and by applying particular levels of pressure and heat, the plating resist 180 may be transcribed onto the surface 124 of the base 120. In order that the plating resist 180 may not be placed inside the trench 122, the carrier 160 may be removed after a particular duration of time. Thus removing the carrier 160 results in the plating resist 180 formed only on the surface 124 of the base 120, as illustrated in FIG. 6.

Referring to FIG. 6, if the carrier 160 is removed after the plating resist 180 is transcribed onto the surface 124 of the base 120, portions of the plating resist 180 that do not correspond to the surface 124 of the base 120 may not be transcribed and may remain on the surface of the carrier 160 to form a remaining part 184. On the surface 124 of the base 120, portions of the plating resist 180 may be transcribed, forming a transcribed part 182. Afterwards, the transcribed part 182 may be cured or dried, in preparation for a plating process.

As such, the transcribed part 182 may be formed by transcribing the plating resist 180 stacked on a film. This can not only provide a uniform thickness, but can also prevent the plating resist 180 from entering the trench 122. Therefore, the occurrence of pin holes may be avoided in the circuit pattern that will be formed in the trench 122, and the circuit pattern can be given a uniform thickness.

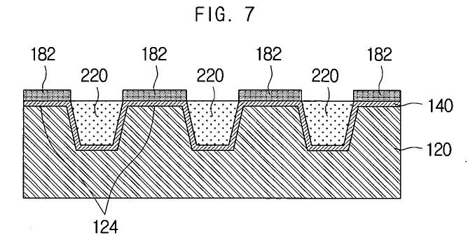

FIG. 7 is a cross-sectional view after forming a pattern 220 in the trench 122 by copper plating.

Referring to FIG. 7, a pattern 220 may be formed inside the trench 122 by copper plating. The pattern 220 can be a circuit pattern, or can be a pattern for forming a via hole that electrically connects circuit patterns located on different layers. The plating may not be formed over the surface 124 of the base 120, because of the transcribed part 182 of the plating resist 180. As the circuit pattern 220 or via hole pattern 220 may be buried in the trench 122, which is formed to a particular depth, the pattern 220 can be formed with a minute thickness and pitch, while peeling or warpage of the pattern 220 may be prevented.

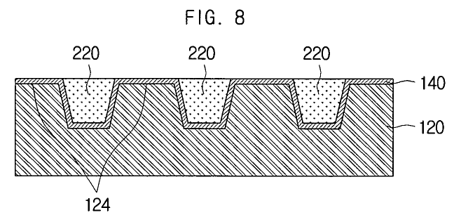

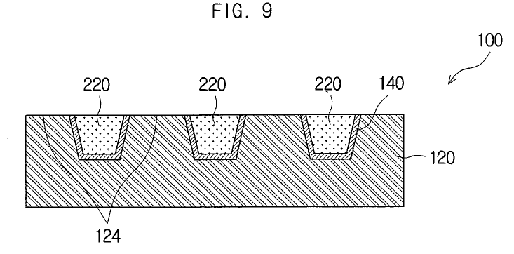

FIG. 8 is a cross-sectional view after removing the transcribed part 182 of the plating resist 180 in FIG. 7, and FIG. 9 is a cross-sectional view after removing portions of the electroless plating layer 140 and the pattern 220.

Referring to FIG. 8, the transcribed part 182 of the plating resist 180 remaining on the surface 124 of the base 120 may be removed by peeling, or by dissolving with a chemical. As a result, the electroless plating layer 140 of the base 120 may be exposed to the exterior. Then, as illustrated in FIG. 9, portions of the electroless plating layer 140 and the pattern 220 may be removed using flash etching.

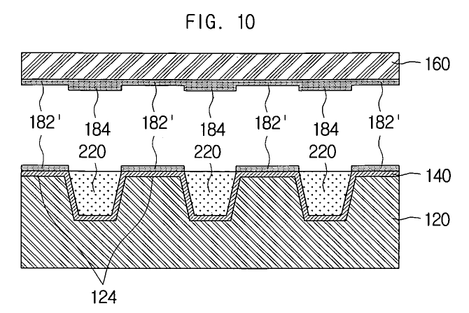

FIG. 10 is a cross-sectional view after removing the carrier, illustrating a transcribed part 182′ formed on the surface 124 of the base 120 with a thickness lower than that of the plating resist 180.

As illustrated in FIG. 10, the transcribed part 182′ transcribed onto the surface 124 of the base 120 may be thinner than the plating resist 180. The thickness of the transcribed part 182′ may be determined by the method of coating the plating resist 180 or by the adhesion between the plating resist 180 and the electroless plating layer 140, etc.

According to certain embodiments of the invention as set forth above, a method of fabricating a circuit board may be provided, with which circuit patterns can be formed with a uniform thickness, and which provides high workability.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of fabricating a circuit board, the method comprising:
forming a trench in a base and forming an electroless plating layer over a surface of the base and an inner surface of the trench;
providing a carrier having a plating resist coated on one side thereof;
forming a transcribed part on the surface of the base by stacking the carrier onto the base and transcribing the plating resist onto the surface of the base;
forming a pattern in the trench by plating, and removing the transcribed part; and
removing portions of the electroless plating layer and the pattern.

2. The method of claim 1, wherein the trench is formed by a laser ablation process or an imprinting process.

3. The method of claim 1, further comprising, after forming the trench:
removing residue from forming the trench and roughening the surface of the base by applying a chemical treatment or a plasma treatment on the surface of the base.

4. The method of claim 1, wherein the plating resist is a resin in one of a liquid, gel, and semi-cured state stacked on the carrier.

5. The method of claim 1, wherein the plating resist has high detachability.

6. The method of claim 5, wherein the plating resist is formed from one of a polystyrene resin, an acrylic resin, and an epoxy resin.

7. The method of claim 1, wherein a thickness of the transcribed part is substantially the same as a thickness of the plating resist.

8. The method of claim 1, wherein a thickness of the transcribed part is lower than a thickness of the plating resist.

9. The method of claim 1, wherein the carrier is formed from polyethylene terephthalate.

10. The method of claim 1, wherein the portions of the electroless plating layer and the pattern are removed by flash etching.
